(19) United States
(12) Patent Application Publication
(10) Pub. No.: US 2024/0234373 A9
(43) Pub. Date: Jul. 11, 2024

(54) MEMORY DEVICE AND SEMICONDUCTOR PACKAGE INCLUDING THE SAME

(71) Applicant: SAMSUNG ELECTRONICS CO., LTD., SUWON-SI (KR)

(72) Inventors: AENEE JANG, SUWON-SI (KR); SEUNGDUK BAEK, SUWON-SI (KR)

(21) Appl. No.: 18/364,127

(22) Filed: Aug. 2, 2023

(30) Foreign Application Priority Data
Oct. 20, 2022 (KR) 10-2022-0135848

(51) Int. Cl. H01L 25/065; H01L 23/00; H01L 25/00; H10B 80/00

(52) U.S. Cl. CPC H01L 25/0657; H01L 24/05; H01L 24/06; H01L 24/08; H01L 24/13; H01L 24/16; H01L 24/29; H01L 24/32; H01L 24/48; H01L 24/49; H01L 24/73; H01L 25/50; H10B 80/00; H01L 24/80; H01L 24/92; H01L 24/94; H01L 24/97; H01L 2224/05553; H01L 2224/05554; H01L 2224/05624; H01L 2224/05644; H01L 2224/05647; H01L 2224/06051; H01L 2224/06132; H01L 2224/06505; H01L 2224/08145; H01L 2224/13147; H01L 2224/16145; H01L 2224/16227; H01L 2224/2919; H01L 2224/32145; H01L 2224/32225; H01L 2224/48091; H01L 2224/48106; H01L 2224/48227; H01L 2224/49175; H01L 2224/73204; H01L 2224/73207; H01L 2224/73253; H01L 2224/73265; H01L 2224/80357; H01L 2224/80379; H01L 2224/80896; H01L 2224/9212; H01L 2224/9222; H01L 2224/92247; H01L 2224/94; H01L 2224/97; H01L 2225/0651; H01L 2225/06513; H01L 2225/06517; H01L 2225/06555; H01L 2924/0554; H01L 2924/0665; H01L 2924/1436

(57) ABSTRACT

A semiconductor package includes a package substrate including a first pad; a first memory device arranged on the package substrate and including first and second semiconductor chips stacked in a vertical direction; and a first chip connecting member electrically connecting the first semiconductor chip to the package substrate. The first semiconductor chip includes a first cell structure; a first peripheral circuit structure; a first bonding pad; and a first input/output pad electrically connected to the first pad of the package substrate through the first chip connection member. The second semiconductor chip includes a second cell structure; and a second bonding pad connected to the first bonding pad. A part of the first peripheral circuit structure protrudes from a sidewall of the second semiconductor chip so as not to overlap the second semiconductor chip.

### CROSS-REFERENCE TO RELATED APPLICATION

This U.S. non-provisional patent application is based on and claims priority under 35 U.S.C. § 119 to Korean Patent Application No. 10-2022-0135848, filed on Oct. 20, 2022, in the Korean Intellectual Property Office, the disclosure of which is incorporated by reference in its entirety herein.

### 1. TECHNICAL FIELD

The inventive concept relates to a memory device and a semiconductor package including the same.

### 2. DISCUSSION OF RELATED ART

An integrated circuit is a set of electronic circuits mounted on a chip of semiconductor material (e.g., a semiconductor chip). Large numbers of transistors and other electronic components are integrated together on the semiconductor chip.

In accordance with the rapid development of the electronics industry and user demands, electronic equipment has become miniaturized, multifunctional, and high-capacity. Accordingly, a large number of semiconductor chips are formed in a semiconductor package mounted on an electronic device to achieve high performance or high capacity.

The semiconductor chips may be mounted side by side or vertically stacked on top of one in one package substrate or vertically stacked on top of one another. Vertically stacking the semiconductor chips may achieve higher integration than side by side mounting. However, reliability of the semiconductor chips may decrease when they are vertically stacked.

### SUMMARY

An exemplary embodiment of the inventive concept provides a semiconductor package including a package substrate including a first pad; a first memory device positioned on the package substrate and including first and second semiconductor chips stacked vertically; and a first chip connection member electrically connecting the first semiconductor chip and the package substrate; wherein the first semiconductor chip includes a first cell structure having a memory cell for storing data; a first peripheral circuit structure that communicates a signal provided from a source located outside the package substrate; a first bonding pad; and a first input/output pad vertically overlapping the first peripheral circuit structure and electrically connected to the first pad of the package substrate through the first chip connection member; wherein the second semiconductor chip includes a second cell structure having a memory cell for storing data; and a second bonding pad connected to the first bonding pad. A part of the first peripheral circuit structure protrudes from the first sidewall of the second semiconductor chip in a first lateral direction so as not to vertically overlap the second semiconductor chip. A length of the first semiconductor chip along the first direction may be greater than a length of the second semiconductor chip along the first direction. The semiconductor package may provide a higher-capacity memory device.

An exemplary embodiment of the inventive concept provides a semiconductor package including a package substrate including a first pad; a memory device disposed on the package substrate and including a first semiconductor chip disposed on the package substrate and a second semiconductor chip disposed on the first semiconductor chip; and a conductive wire electrically connecting the first semiconductor chip and the package substrate. The first semiconductor chip includes a first cell structure having a memory cell for storing data; a first peripheral circuit structure that communicates a signal provided from a source located outside the semiconductor package; a first interconnect structure including a first bonding pad and a first input/output pad electrically connected to the first pad of the package substrate through the conductive wire, wherein the first input/output pad is vertically overlapped with the first peripheral circuit structure. The second semiconductor chip includes a second cell structure having a memory cell for storing data; and a second interconnect structure including a second bonding pad directly coupled to the first bonding pad. A part of the first peripheral circuit structure protrudes from a first sidewall of the second semiconductor chip in a first direction so as not to vertically overlap the second semiconductor chip, wherein a thickness of the second semiconductor chip is smaller than a thickness of the first semiconductor chip. The thickness of the second semiconductor chip may be between about 10 micrometers and about 100 micrometers. A length of the first semiconductor chip along the first direction may be greater than a length of the second semiconductor chip along the first direction. The semiconductor package may provide a higher-capacity memory device.

An exemplary embodiment of the inventive concept provides a memory device including a first semiconductor chip including a first cell structure having memory cells for storing data, a first peripheral circuit structure that communicates a signal provided from a source located outside the memory device, a first bonding pad and first input/output pad; and a second semiconductor chip stacked on the first semiconductor chip, including a second cell structure having memory cells for storing data and a second bonding pad connected to the first bonding pad. A length of the first semiconductor chip along a first direction is greater than a length of the second semiconductor chip along the first direction. A part of the first peripheral circuit structure protrudes from the first sidewall of the second semiconductor chip in the first lateral direction so as not to vertically overlap the second semiconductor chip. The semiconductor package may provide a higher-capacity memory device.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an embodiment of the present inventive concept;

FIG. 2 is a plan view of the semiconductor package according to an embodiment of the present inventive concept;

FIG. 3 is a plan view of a first semiconductor chip of a memory device according to an embodiment of the present inventive concept;

FIGS. 4 and 5 are block diagrams for the configuration of the memory device of FIG. 1;

FIGS. 6A to 6E are cross-sectional views of stages in a method of manufacturing a semiconductor package, according to an embodiment of the present inventive concept;

FIG. 7A is a plan view of a memory device according to an embodiment of the present inventive concept;

FIG. 7B is a plan view of a memory device according to an embodiment of the present inventive concept;

FIG. 8 is a cross-sectional view of a semiconductor package according to an embodiment of the present inventive concept;

FIG. 9 is a cross-sectional view of a semiconductor package according to an embodiment of the present inventive concept;

FIG. 10 is a cross-sectional view of a semiconductor package according to an embodiment of the present inventive concept;

FIG. 11 is a cross-sectional view of a semiconductor package according to an embodiment of the present inventive concept;

FIG. 12 is a cross-sectional view of a semiconductor package according to an embodiment of the present inventive concept;

FIG. 13 is a block diagram for an example of a memory system including a semiconductor package according to an embodiment of the present inventive concept.

### DETAILED DESCRIPTION OF THE EMBODIMENTS

Hereinafter, embodiments will be described with reference to the attached drawings. In the drawings, like numerals denote like elements and redundant descriptions thereof will be omitted.

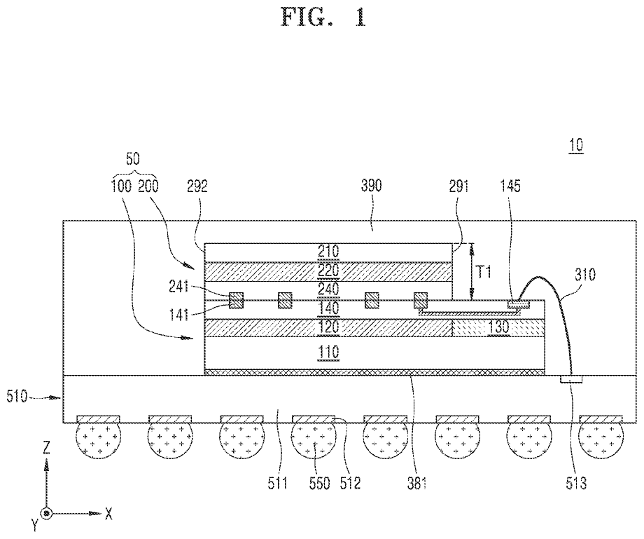

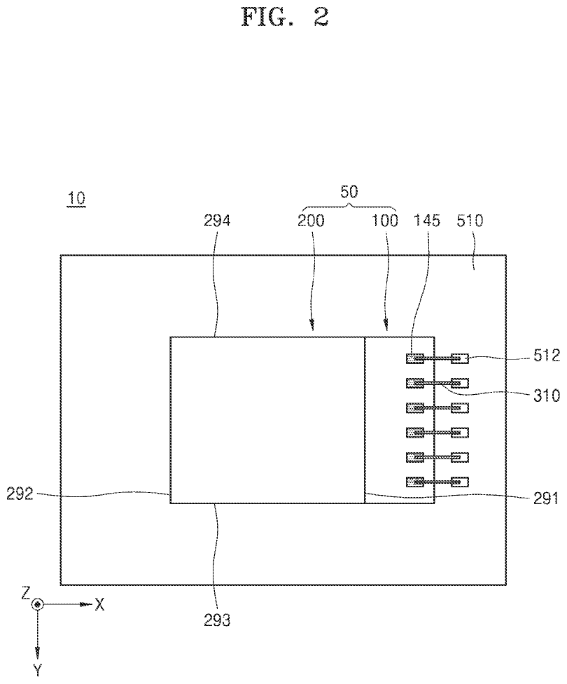

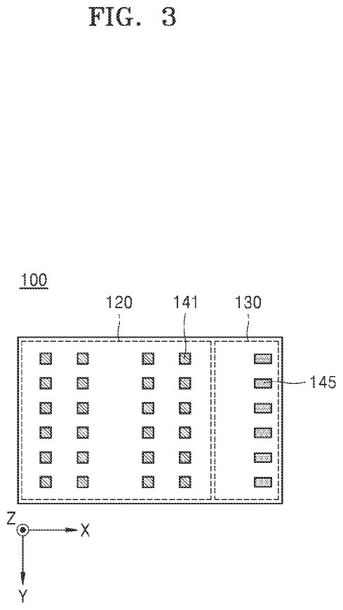

FIG. 1 is a cross-sectional view of a semiconductor package 10 according to embodiments of the present inventive concept. FIG. 2 is a plan view of the semiconductor package 10 according to an embodiment of the present inventive concept. FIG. 3 is a plan view of a first semiconductor chip 100 of the first memory device 50 according to an embodiment of the present inventive concept.

Referring to FIGS. 1 to 3, the semiconductor package 10 may include a package substrate 510 and the first memory device 50 mounted on the package substrate 510. The first memory device 50 may include semiconductor chips that are vertically stacked and electrically connected to each other.

For example, the package substrate 510 may include a printed circuit board (PCB). The package substrate 510 may include a core insulating layer 511, first upper connection pads 513, and lower connection pads 512. The first upper connection pads 513 and the lower connection pads 512 may each include a conductive material. As shown in FIG. 2, the input/output pads 145 may be connected to the lower connection pads 512 via first chip connection members 310. The first chip connection members 310 may include conductive wires.

The package substrate 510 may have a plate or substantially plate shape. The package substrate 510 may have a panel or substantially panel shape. The package substrate 510 may include upper and lower surfaces that are opposite to each other, and the upper and lower surfaces of the package substrate 510 may each be flat or substantially flat. Hereinafter, the horizontal direction (e.g., X direction and/or Y direction) may be defined as a direction parallel to the upper surface of the package substrate 510, and the vertical direction (e.g., Z direction) may be defined as a direction perpendicular to the upper surface of the package substrate 510.

The core insulating layer 511 may include at least one material selected from phenol resin, epoxy resin, and polyimide. For example, the core insulating layer 511 may include at least one material selected from polyimide, flame retardant 4 (FR4), tetrafunctional epoxy, polyphenylene ether, epoxy/polyphenylene oxide, bismaleimide triazine (BT), thermount, cyanate ester, and liquid crystal polymer.

The first upper connection pads 513 may be provided on the upper surface of the core insulating layer 511. The lower connection pads 512 may be provided on the lower surface of the core insulating layer 511. The upper surface may oppose the lower surface. An internal interconnect for electrically connecting the first upper connection pads 513 to the lower connection pads 512 may be provided inside the core insulating layer 511. For example, the internal interconnect may be a conductive element such as a wire.

For example, the first upper connection pads 513 may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

External connectors 550 may be respectively attached to the lower connection pads 512 of the package substrate 510. The external connectors 550 may be configured to electrically and physically connect the package substrate 510 and an external device on which the package substrate 510 is mounted. For example, the external connectors 550 may include a solder ball or a solder bump.

The first memory device 50 may include the first semiconductor chip 100 and a second semiconductor chip 200 that is stacked in a vertical direction on top of the first semiconductor chip 100 and electrically and physically connected to the first semiconductor chip 100. As illustrated in FIG. 1, the second semiconductor chip 200 may be stacked on the first semiconductor chip 100, but is not limited thereto. For example, two or more second semiconductor chips 200 may be arranged side-by-side along an upper surface of the first semiconductor chip 100.

The first semiconductor chip 100 and the second semiconductor chip 200 may be of the same or different types. The first semiconductor chip 100 and the second semiconductor chip 200 may each include a memory chip, a logic chip, a system on chip (SoC), a power management integrated circuit (PMIC) chip, a radio frequency integrated circuit (RFIC) chip, or the like. The memory chip may include a DRAM chip, an MRAM chip, a NAND flash memory chip, and/or a high bandwidth memory (HBM) chip. The logic chip may include an application processor (AP), a microprocessor, a central processing unit (CPU), a controller, and/or application specific integrated circuit (ASIC).

In the following embodiments, each of the first semiconductor chip 100 and the second semiconductor chip 200 is described as a memory chip, e.g., a DRAM chip, but is not limited thereto.

Dimensions of the first semiconductor chip 100 may be different from the dimensions of the second semiconductor chip 200. In embodiments, the footprint of the first semiconductor chip 100 may be greater than the footprint of the second semiconductor chip 200. In an embodiments, the horizontal length of the first semiconductor chip 100 in a first direction X is greater than the horizontal length of the second semiconductor chip 200 in the first direction X. In an embodiment, the thickness of the first semiconductor chip 100 (i.e., the vertical length of the first semiconductor chip 100) in a second direction Z is greater than the thickness of the second semiconductor chip 200 (i.e., the vertical length of the second semiconductor chip 200) in the second direction Z.

In an embodiment, a part of the first semiconductor chip 100 protrudes from the second semiconductor chip 200 in a first lateral direction (e.g., X direction). In an embodiment, a part of the first semiconductor chip 100 protrudes from a first sidewall 291 of the second semiconductor chip 200 in a first lateral direction (e.g., X direction), and one sidewall of the first semiconductor chip 100 may be vertically aligned with a second sidewall 292 of the second semiconductor chip 200 opposite to the first sidewall 291 of the second semiconductor chip 200. The second semiconductor chip 200 may additionally include a second sidewall 292, a third sidewall 293, and a fourth sidewall 294. Since a part of the first semiconductor chip 100 protrudes from the second semiconductor chip 200 in a first lateral direction (e.g., X direction), an outer surface of the first memory device 50 may have steps. For example, a side surface of the first memory device 50 may have a stepped structure. The height of the step on the outer surface of the first memory device 50 may be defined by a thickness of the second semiconductor chip 200 or by a difference between the vertical height level of the upper surface of the first semiconductor chip 100 and the vertical height level of the upper surface of the second semiconductor chip 200. In an embodiment, a thickness T1 of the second semiconductor chip 200 is between about (or precisely) 10 micrometers and about (or precisely) 100 micrometers, between about (or precisely) 10 micrometers and about (or precisely) 80 micrometers, between about (or precisely) 10 micrometers and about (or precisely) 60 micrometers, or between about (or precisely) 10 micrometers and about (or precisely) 40 micrometers. In an embodiment, a vertical distance between the upper surface of the first semiconductor chip 100 and the upper surface of the second semiconductor chip 200 is equal to the thickness T1 of the second semiconductor chip 200.

The first semiconductor chip 100 may be fixed onto the upper surface of the package substrate 510 by using an adhesive member 381 such as a die attach film. The first semiconductor chip 100 may include a first semiconductor substrate 110, a first cell structure 120, a first peripheral circuit structure 130, and a first interconnect structure 140.

The first semiconductor substrate 110 may be formed from a semiconductor wafer. For example, the first semiconductor substrate 110 may include silicon (Si). Alternatively, the first semiconductor substrate 110 may include a semiconductor element, such as germanium (Ge), or a compound semiconductor, such as silicon carbide (SiC), gallium arsenide (GaAs), indium arsenide (InAs), or indium phosphide (InP). The first semiconductor substrate 110 may include a conductive region, e.g., an impurity-doped well or an impurity-doped structure. The first semiconductor substrate 110 may include an active surface and an inactive surface that are opposite to each other. In an embodiment, the active surface of the first semiconductor substrate 110 is an upper surface of the first semiconductor substrate 110, and the inactive surface of the first semiconductor substrate 110 is a lower surface of the first semiconductor substrate 110. The inactive surface of the first semiconductor substrate 110 may contact the adhesive member 381.

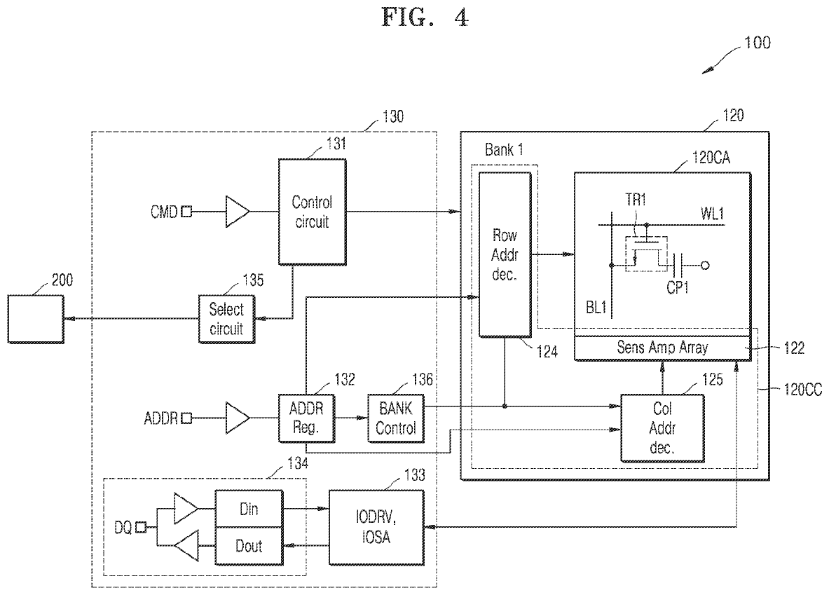

The first cell structure 120 and the first peripheral circuit structure 130 may be formed on and/or within the active surface of the first semiconductor substrate 110. The first cell structure 120 and the first peripheral circuit structure 130 may be positioned side by side in a first lateral direction (e.g., X direction) along the active surface of the first semiconductor substrate 110 and form a circuit element layer of the first semiconductor chip 100 covering the active surface of the first semiconductor substrate 110. The first cell structure 120 may include a memory cell for storing data. The first cell structure 120 may include a first cell array structure (120CA of FIG. 4) and a first core circuit structure (120CC of FIG. 4). The first cell array structure 120CA and the first core circuit structure 120CC may be positioned side by side in a first lateral direction (e.g., X direction) along the active surface of the first semiconductor substrate 110. For example, the first core circuit structure 120CC may be positioned between the first cell array structure 120CA and the first peripheral circuit structure 130. The first peripheral circuit structure 130 may be a region that provides an interface to communicate signals (e.g., data signals, power signals, and/or control signals) provided from an external device (e.g., a memory controller).

The first interconnect structure 140 may be positioned on the first cell structure 120 and the first peripheral circuit structure 130 and cover the first cell structure 120 and the first peripheral circuit structure 130. The first interconnect structure 140 may include an interconnect insulating layer and multi-layered conductive layers covered by the interconnect insulating layer. The interconnect insulating layer may include an insulating polymer, an epoxy, or a combination thereof. The conductive layers may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or alloys thereof.

The first interconnect structure 140 may include first bonding pads 141 and input/output pads 145 arranged in the upper surface of the first semiconductor chip 100.

The first bonding pads 141 may constitute an electrical connection path between the second semiconductor chip 200 and the first semiconductor chip 100. The first bonding pads 141 may be positioned to vertically overlap the second semiconductor chip 200 and may also be positioned to vertically overlap the first cell structure 120. The first bonding pads 141 may include a metal or a conductive material, e.g., copper (Cu). As shown in FIG. 3, the first bonding pads 141 may be spaced apart from one another and arranged in rows and columns but is not limited thereto.

The input/output pads 145 may constitute an electrical connection path between the first memory device 50 and the package substrate 510. As shown in FIG. 3, the input/output pads 145 may be spaced apart from one another and arranged in a column but is not limited thereto. The input/output pads 145 may be positioned to vertically overlap the first peripheral circuit structure 130, but not to vertically overlap the second semiconductor chip 200. The input/output pads 145 may be positioned adjacent to one edge of the upper surface of the first semiconductor chip 100 and may be arranged along a straight line parallel to the edge of the upper surface of the first semiconductor chip 100. At least one of the input/output pads 145 may be electrically connected to at least one of the first bonding pads 141 through a conductive line of the first interconnect structure 140. The conductive line may be submerged entirely within the first interconnect structure 140. The input/output pads 145 may include a metal or conductive material, e.g., copper. In embodiments, each of the input/output pads 145 may include multiple metal layers, e.g., multiple metal layers formed of a combination of a Cu layer, an aluminum (Al) layer, and a gold (Au) layer.

The second semiconductor chip 200 may be stacked on the first semiconductor chip 100 so as not to cover the input/output pads 145. The second semiconductor chip 200 may vertically overlap the first cell structure 120 of the first semiconductor chip 100. At least a part of the first peripheral circuit structure 130 of the first semiconductor chip 100 may protrude from a sidewall of the second semiconductor chip 200 in a first lateral direction (e.g., X direction) so as not to vertically overlap the second semiconductor chip 200. In an embodiment, the entirety of the first peripheral circuit structure 130 of the first semiconductor chip 100 protrudes from the sidewall of the second semiconductor chip 200 in the first lateral direction (e.g., X direction) so as not to vertically overlap the second semiconductor chip 200.

The second semiconductor chip 200 may include a second semiconductor substrate 210, a second cell structure 220, and a second interconnect structure 240.

The material of the second semiconductor substrate 210 may be substantially the same as that of the first semiconductor substrate 110. The second semiconductor substrate 210 may include a conductive region, e.g., an impurity-doped well or an impurity-doped structure. The second semiconductor substrate 210 may include an active surface and an inactive surface that are opposite to each other. In an embodiment, the active surface of the second semiconductor substrate 210 is a lower surface of the second semiconductor substrate 210 facing the first semiconductor chip 100, and the inactive surface of the second semiconductor substrate 210 is an upper surface of the second semiconductor substrate 210. The upper surface may oppose the lower surface.

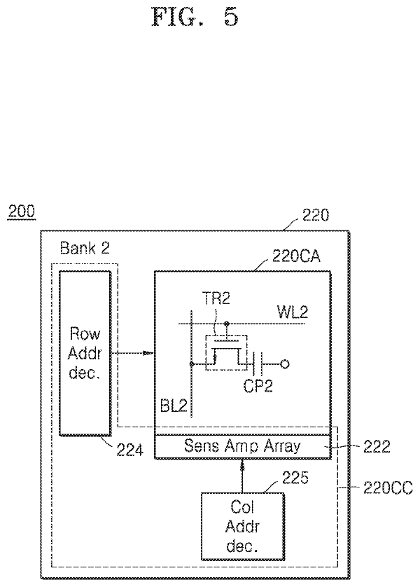

The second cell structure 220 may be formed on and/or within the active surface of the second semiconductor substrate 210. The second cell structure 220 may constitute a circuit element layer of the second semiconductor chip 200 covering the active surface of the second semiconductor substrate 210. The second cell structure 220 may include a memory cell for storing data. The second cell structure 220 may include a second cell array structure (220CA of FIG. 5) and a second core circuit structure (220CC of FIG. 5). The second cell array structure 220CA and the second core circuit structure 220CC may be positioned side by side in a first lateral direction (e.g., X direction) along the active surface of the second semiconductor substrate 210.

The second interconnect structure 240 may be positioned below the second cell structure 220 and may be positioned between the second cell structure 220 and the upper surface of the first semiconductor chip 100. The second interconnect structure 240 may contact the first interconnect structure 140 of the first semiconductor chip 100. The second interconnect structure 240 may include an interconnect insulating layer and multi-layered conductive layers covered by the interconnect insulating layer. The material of the interconnect insulating layer of the second interconnect structure 240 may be the same as the material of the interconnect insulating layer of the first interconnect structure 140, and the material of the conductive layers of the second interconnect structure 240 may be the same as the material of the conductive layers of the first interconnect structure 140.

The second interconnect structure 240 may include second bonding pads 241 arranged in a lower surface of the second semiconductor chip 200. The second bonding pads 241 may be vertically aligned with the first bonding pads 141. The second bonding pads 241 may be electrically and physically connected to the first bonding pads 141. The first semiconductor chip 100 and the second semiconductor chip 200 may be electrically connected through the electrical connection between the second bonding pads 241 and the first bonding pads 141. The second bonding pads 241 may include metal or a conductive element, e.g., copper.

In an embodiment, the first semiconductor chip 100 and the second semiconductor chip 200 are bonded by using a direct bonding method, e.g., a copper-to-copper (Cu-to-Cu) bonding method or a hybrid bonding method. The first bonding pads 141 may directly contact and be coupled to the second bonding pads 241. Furthermore, when the first semiconductor chip 100 is bonded to the second semiconductor chip 200 by a hybrid bonding method, each of the interconnect insulating layer of the first interconnect structure 140 and the interconnect insulating layer of the second interconnect structure 240 may include a silicon oxide layer, and an upper surface of the interconnect insulating layer of the first interconnect structure 140 and a lower surface of the interconnect insulating layer of the second interconnect structure 240 may each have a bonding strength suitable for bonding through plasma treatment and/or wet treatment. The upper surface of the interconnect insulating layer of the first interconnect structure 140 may be bonded to the lower surface of the interconnect insulating layer of the second interconnect structure 240.

The semiconductor package 10 may include first chip connection members 310 configured to electrically connect the first memory device 50 to the package substrate 510. The first chip connection members 310 may include conductive wires configured to electrically connect the first upper connection pads 513 of the package substrate 510 to the input/output pads 145 of the first semiconductor chip 100. Each of the conductive wires may extend beyond the sidewall of the first semiconductor chip 100 from the corresponding first upper connection pad 513 to the corresponding input/output pad 145. The conductive wires may be formed through a bonding wire process.

Electrical signals to be communicated between the first memory device 50 and the package substrate 510 may be transmitted through the first chip connection members 310. Input signals received through the external connectors 550 of the package substrate 510 may be transmitted to the input/output pads 145 of the first semiconductor chip 100 through the first chip connection members 310. The input signals may include a command signal, an address signal, a data input signal, a power signal (supply voltage (i.e., Vdd voltage) and ground voltage (i.e., Vss voltage)), and the like. Input signals received through the input/output pads 145 of the first semiconductor chip 100 may be transmitted through the conductive layers of the first interconnect structure 140 of the first semiconductor chip 100 to the first cell array circuit of the first cell array structure 120CA, the first core circuit of the first core circuit structure 120CC, and/or the first peripheral circuit of the first peripheral circuit structure 130. The input signals received through the input/output pads 145 of the first semiconductor chip 100 may be transmitted through an electrical path including the conductive layers of the first interconnect structure 140, the first bonding pads 141, the second bonding pads 241, and the conductive layers of the second interconnect structure 240 to the second cell array circuit of the second cell array structure 220CA and/or the second core circuit of the second core circuit structure 220CC. In addition, output signals output from the first semiconductor chip 100 may be transmitted to an external device through an electrical path including the input/output pads 145, the first chip connection members 310, and the external connectors 550 to an external device. Output signals output from the second semiconductor chip 200 may be transmitted to an external device through an electrical path including the second bonding pads 241, the first bonding pads 141, conductive layers of the first interconnect structure 140, the input/output pads 145, the first chip connection members 310, and the external connectors 550.

In an embodiment of the present inventive concept, the second semiconductor chip 200 does not include any peripheral circuit, and the first peripheral circuit of the first peripheral circuit structure 130 of the first semiconductor chip 100 is configured to control a circuit of the first cell structure 120 of the first semiconductor chip 100 and a circuit of the second cell structure 220 of the second semiconductor chip 200. Thus, the first peripheral circuit structure 130 may be shared by the first cell structure 120 and the second cell structure 220. The first semiconductor chip 100 may be referred to as a master chip, and the second semiconductor chip 200 may be referred to as a slave or subordinate chip. Since the memory device 50 comprising a plurality of semiconductor chips can be used as a single device, the memory device 50 may achieve a high storage capacity. Furthermore, since the first semiconductor chip 100 and the second semiconductor chip 200 are vertically stacked in the memory device 50, the memory device 50 may have a small footprint while having a high-capacity memory.

The semiconductor package 10 may further include a molding layer 390 arranged on the package substrate 510. The molding layer 390 may cover the upper surface of the package substrate 510 and the memory device 50. The molding layer 390 may surround sidewalls of the first semiconductor chip 100 and may extend along the sidewalls of the first semiconductor chip 100. The molding layer 390 may surround sidewalls of the second semiconductor chip 200 and may extend along the sidewalls of the second semiconductor chip 200. In an embodiment, the molding layer 390 covers the memory device 50 so that the memory device 50 is not exposed to the outside of the semiconductor package 10. In an embodiment, the molding layer 390 covers a part of the memory device 50 and exposes another part of the memory device 50 to the outside of the semiconductor package 10. For example, the upper surface of the memory device 50 (i.e., the upper surface of the second semiconductor chip 200) may be exposed to the outside of the semiconductor package 10 without being covered by the molding layer 390. For example, an upper surface of the second semiconductor substrate 210 need not be covered by the molding layer 390 as shown in FIG. 1 so that the upper surface is exposed.

For example, the molding layer 390 may include epoxy-based molding resin or polyimide-based molding resin. In an embodiment, the molding layer 390 includes an epoxy molding compound.

FIGS. 4 and 5 are block diagrams for the configuration of the memory device 50 of FIG. 1.

FIG. 4 is a configuration diagram for the first semiconductor chip 100 of the memory device 50 of FIG. 1, and FIG. 5 is a configuration diagram for the second semiconductor chip 200 of the memory device 50 of FIG. 1.

Referring to FIGS. 1, 4, and 5, the first semiconductor chip 100 may include the first cell structure 120 and the first peripheral circuit structure 130. The first cell structure 120 shown in FIG. 4 represents one of the cell structures formed in the first semiconductor chip 100, i.e., a bank (e.g., Bank 1).

The first cell structure 120 (e.g., a circuit) includes a first cell array structure 120CA and a first core circuit structure 120CC (e.g., a circuit). The first cell array structure 120CA may include a first cell array circuit. The first cell array circuit may include a transistor TR1, a word line WL1 connected to a gate of the transistor TR1, a bit line BL1 connected to one end of the transistor TR1, and a capacitor structure CP1 (e.g., a capacitor) connected to the other end of the transistor TR1. The capacitor structure CP1 is a storage structure configured to store charge and may include a dielectric layer and two electrodes spaced apart from each other with the dielectric layer therebetween. The first core circuit structure 120CC may include a first core circuit. The first core circuit may include a first sense amplifier array 122, a first row address decoder 124 (e.g., a decoder circuit), a first column address decoder 125 (e.g., a decoder circuit), a sub-word line driver, and the like. The first sense amplifier array 122 may include a circuit configured to sense and amplify charge input to the first cell array circuit or charge output from the first cell array circuit. The first core circuit may transmit data sensing signals, read signals and write signals for the first cell array circuit by using the first sense amplifier array 122, the first row address decoder 124, and the first column address decoder 125.

The first peripheral circuit structure 130 may include a first peripheral circuit. The first peripheral circuit may control the first cell array circuit and the first core circuit and receive and transmit data input/output signals.

More specifically, the first peripheral circuit may include a first control circuit 131 that receives external command signals (or commands) CMD and generates control signals in response thereto. The first peripheral circuit may include an address register 132 that receives address signals (or addresses) ADDR and provides the address signals ADDR to the first row address decoder 124 and the first column address decoder 125. The first peripheral circuit may include a bank controller (e.g., a controller circuit) 136 for controlling bank selection and the like when memory operations are controlled in BANK units. The first peripheral circuit may include a first input/output sense amplifier and a first input/output driver (e.g., a driver circuit) 133 for receiving and transmitting data input/output signals DQ, and a first data input/output unit (e.g., an input/output circuit) 134. In FIG. 4, Din represents a data input terminal and Dout represents a data output terminal.

In addition, the first peripheral circuit may include a first select circuit 135 connected to the first control circuit 131. The first select circuit 135 may be a switch circuit or a fuse circuit. The semiconductor package 10 may select and control the first semiconductor chip 100 and/or the second semiconductor chip 200 using the first control circuit 131 and the first select circuit 135. In the semiconductor package 10, even when one of the first semiconductor chip 100 and the second semiconductor chip 200 does not operate, the other chip may operate, thereby significantly improving the reliability of the semiconductor package 10.

The second semiconductor chip 200 may include a second cell structure 220 connected to the first peripheral circuit of the first peripheral circuit structure 130. The second cell structure 220 shown in FIG. 5 represents one of the cell structures formed in the second semiconductor chip 200, i.e., a bank (e.g., Bank 2).

The second cell structure 220 may include a second cell array structure 220CA and a second core circuit structure 220CC. The second cell array structure 220CA may include a second cell array circuit. The second cell array circuit may include a transistor TR2, a word line WL2 connected to a gate of the transistor TR2, a bit line BL2 connected to one end of the transistor TR2, and a capacitor structure CP2 connected to the other end of the transistor TR2. The capacitor structure CP2 (e.g., a capacitor) is a storage structure configured to store charge and may include a dielectric layer and two electrodes spaced apart from each other with the dielectric layer therebetween. The second core circuit structure 220CC may include a second core circuit. The second core circuit may include a second sense amplifier array 222, a second row address decoder 224 (e.g., a decoder circuit), a second column address decoder 225 (e.g., a decoder circuit), a sub-word line driver, and the like. The second sense amplifier array 222 may include a circuit configured to sense and amplify charge input to the second cell array circuit or charge output from the second cell array circuit. The second core circuit may transmit data sensing signals, read signals, and write signals of the second cell array circuit by using the second sense amplifier array 222, the second row address decoder 224, and the second column address decoder 225. The first peripheral circuit of the first peripheral circuit structure 130 may control the second cell array circuit and the second core circuit and receive and transmit data input/output signals.

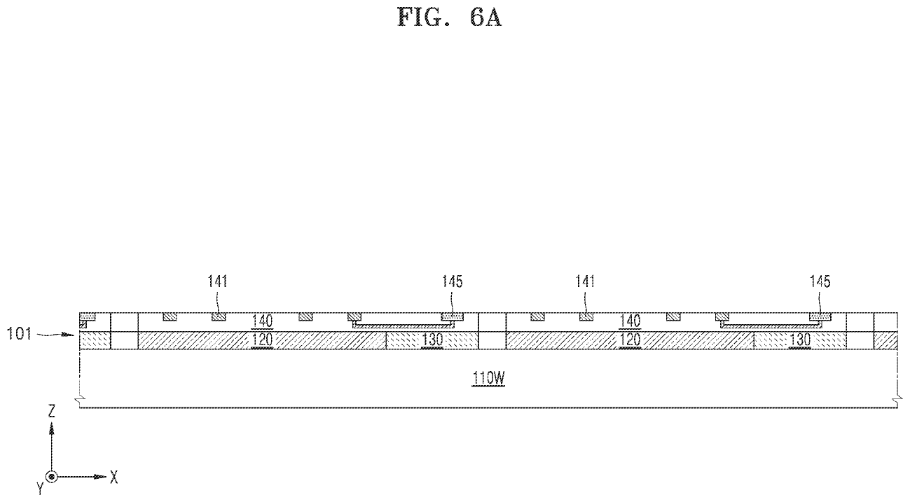

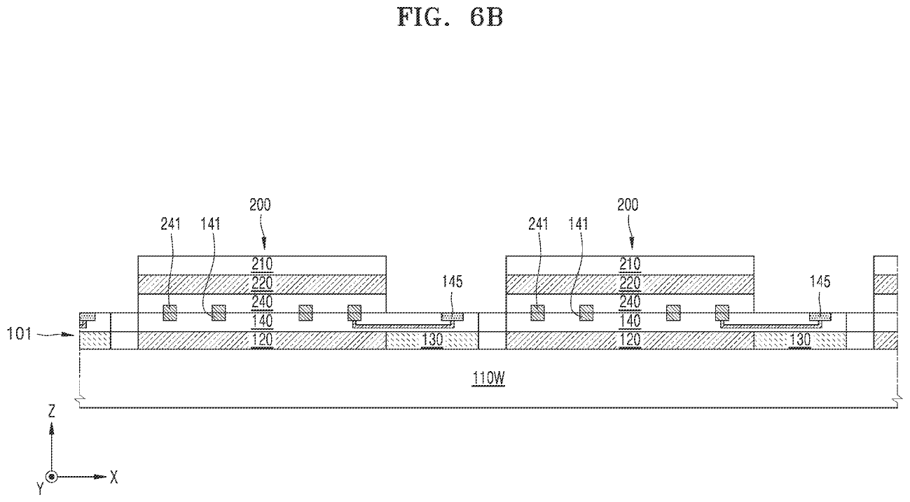

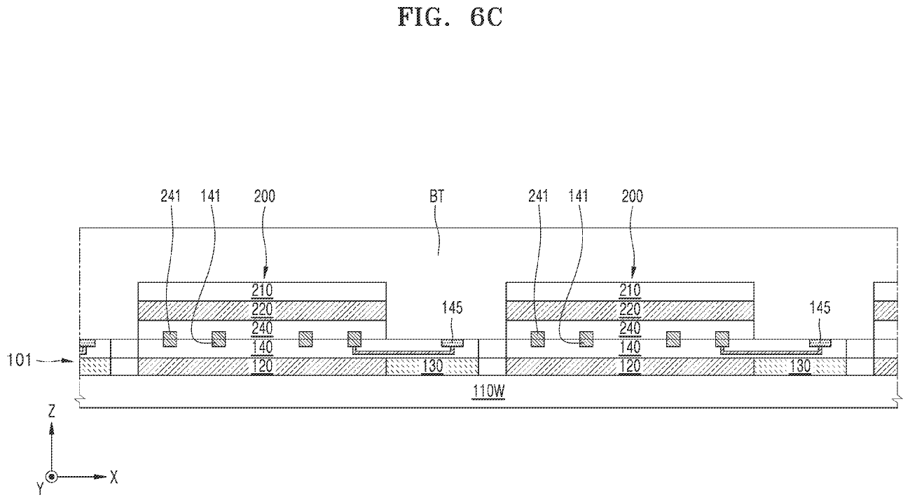

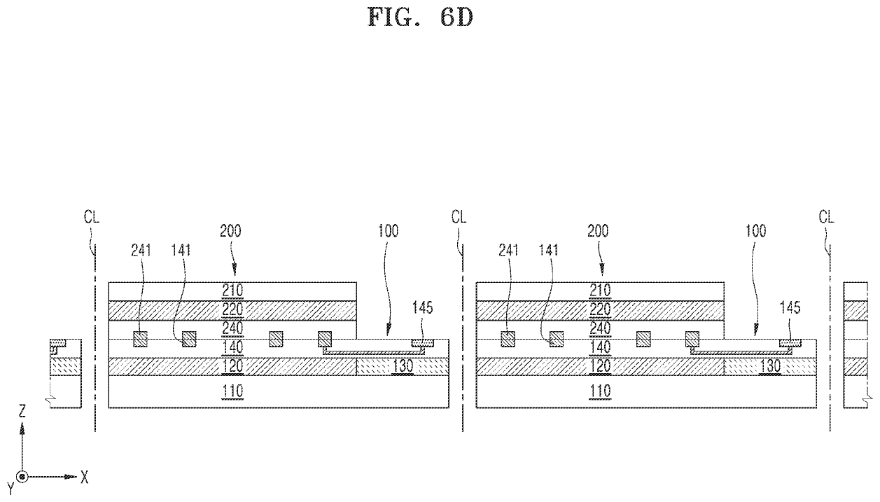

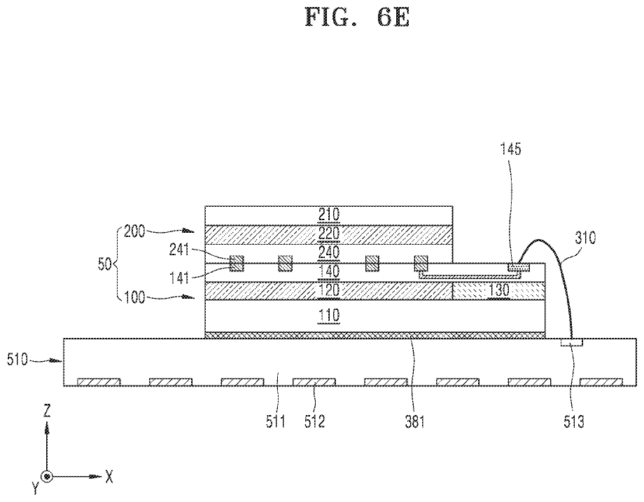

FIGS. 6A to 6E are cross-sectional views of stages in a method of manufacturing a semiconductor package, according to an embodiment of the present inventive concept. Hereinafter, a method of manufacturing the semiconductor package 10 described with reference to FIG. 1 is described with reference to FIGS. 6A to 6E.

Referring to FIG. 6A, a semiconductor wafer 110W is formed, the circuit element layer is formed on the semiconductor wafer 110W and the first interconnect structure 140 is formed on the circuit element layer. The circuit element layer may include the first cell structure 120 and the first peripheral circuit structure 130. The first interconnect structure 140 may include the first bonding pads 141 and the input/output pads 145 exposed upward. For example, an upper surface of the first bonding pads 141 and the input/output pads 145 may be exposed. The semiconductor wafer 110W, the circuit element layer, and the first interconnect structure 140 may constitute a flat or substantially flat semiconductor structure 101.

Referring to FIG. 6B, second semiconductor chips 200 are mounted on the flat semiconductor structure 101. The second semiconductor chips 200 may be stacked on the flat semiconductor structure 101 so as not to cover the input/output pads 145. Each of the second semiconductor chips 200 may be bonded to the first interconnect structure 140 through a direct bonding method or hybrid bonding method. At bonding pads 141 between each of the second semiconductor chips 200 and the first interconnect structure 140, the first bonding pads 141 may directly contact the bonding pads 241.

Referring to FIG. 6C, support tape BT is attached onto the flat semiconductor structure 101 and the second semiconductor chips 200, and a back grinding process is performed on the semiconductor wafer 110W from the lower side of the semiconductor wafer 110W. Through the back grinding process, a part of the semiconductor wafer 110W may be removed and a thickness of the semiconductor wafer 110W may be reduced.

Referring to FIGS. 6C and 6D, after removing the support tape BT from the result of FIG. 6C, a cutting process of cutting the flat semiconductor structure 101 along the cutting line CL is performed. Through the cutting process, the flat semiconductor structure 101 may be separated into the first semiconductor chips 100. The first semiconductor chip 100 and the second semiconductor chip 200 attached thereto may constitute the memory device (e.g., 50 in FIG. 1).

Referring to FIG. 6E, the memory device 50 is mounted on the package substrate 510. The memory device 50 may be attached to the upper surface of the package substrate 510 by using the adhesive member 381. Thereafter, first chip connection members 310 electrically connecting first input/output terminals of the first semiconductor chip 100 to the first upper connection pads 513 of the package substrate 510 are formed. Each of the first chip connection members 310 may include a conductive wire formed through a bonding wire process.

Referring to FIG. 1, a molding layer 390 covering the memory device 50 and the first chip connecting members 310 is formed on the package substrate 510. For example, the molding layer 390 may be formed through a molding process using an epoxy-molding-compound (EMC). Thereafter, the external connectors 550 attached to the lower side of the package substrate 510 may be formed by performing a solder ball attach process and a reflow process.

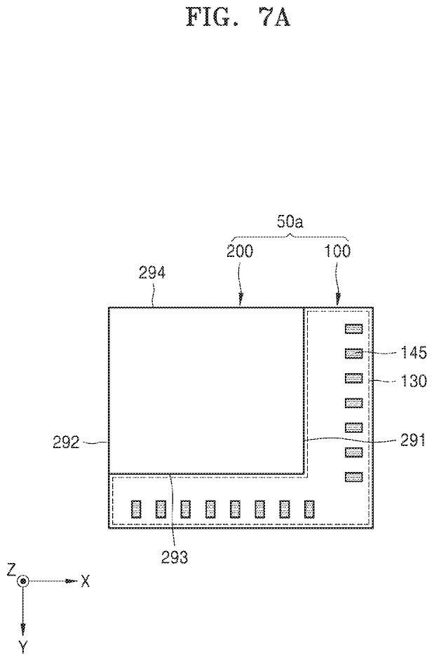

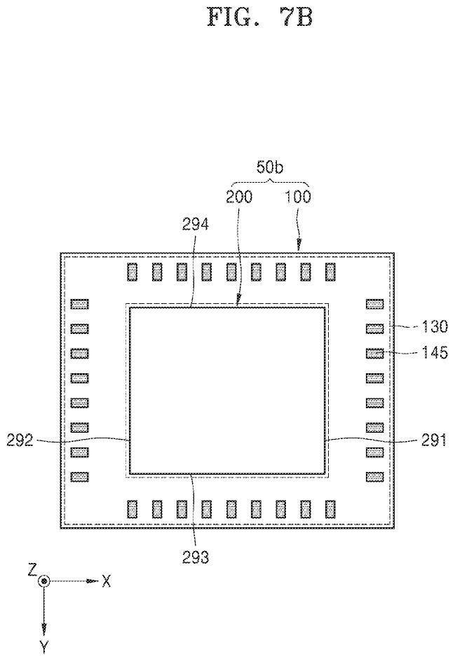

FIGS. 7A and 7B are plan views of memory devices 50a and 50b, respectively, according to embodiments of the present invention. Memory device 50a or memory device 50b may be used to implement memory device 50.

Referring to FIG. 7A, in the memory device 50a, a first part of the first semiconductor chip 100 may protrude from a first sidewall 291 of the second semiconductor chip 200 in a first lateral direction (e.g., X direction), and a second part of the first semiconductor chip 100 may protrude from a third sidewall 293 of the second semiconductor chip 200 connected to the first sidewall 291 in a second lateral direction (e.g., Y direction) perpendicular to the first lateral direction (e.g., X direction). The upper surfaces of the first part and the second part of the first semiconductor chip 100 are not covered by the second semiconductor chip 200, and the input/output pads 145 may be provided on the upper surfaces of the first part and the second part of the first semiconductor chip 100. In a plan view, a protruding part of the first semiconductor chip 100 that does not vertically overlap the second semiconductor chip 200 may extend along the first sidewall 291 and the third sidewall 293 of the second semiconductor chip 200. The first peripheral circuit structure 130 of the first semiconductor chip 100 may be provided in the first part and the second part of the first semiconductor chip 100. That is, the first peripheral circuit structure 130 of the first semiconductor chip 100 may protrude from the first sidewall 291 of the second semiconductor chip 200 in a first lateral direction (e.g., X direction) not to vertically overlap the second semiconductor chip 200, and may also protrude from the third sidewall 293 of the second semiconductor chip 200 in the second lateral direction (e.g., Y direction) so as not to vertically overlap the second semiconductor chip 200.

Referring to FIG. 7B, in the memory device 50b, the first semiconductor chip 100 may protrude laterally from each of the first to fourth sidewalls 291, 292, 293, and 294 of the second semiconductor chip 200. In a plan view, the protruding part of the first semiconductor chip 100 that does not vertically overlap the second semiconductor chip 200 may extend along the first to fourth sidewalls 291, 292, 293, and 294 of the second semiconductor chip 200. In the first semiconductor chip 100, the input/output pads 145 may be positioned on an upper surface of the protruding part of the first semiconductor chip 100 that does not vertically overlap the second semiconductor chip 200. In a plan view, the input/output pads 145 may be arranged along imaginary lines surrounding the first to fourth sidewalls 291, 292, 293, and 294 of the second semiconductor chip 200. For example, the input/output pads 145 may be spaced apart from an outer boundary of the second semiconductor chip 200. The first peripheral circuit structure 130 of the first semiconductor chip 100 may be provided in the protruding part of the first semiconductor chip 100 that does not vertically overlap the second semiconductor chip 200. That is, the first peripheral circuit structure 130 of the first semiconductor chip 100 may protrude laterally from each of the first to fourth sidewalls 291, 292, 293, and 294 of the second semiconductor chip 200 so as not to vertically overlap the second semiconductor chip 200.

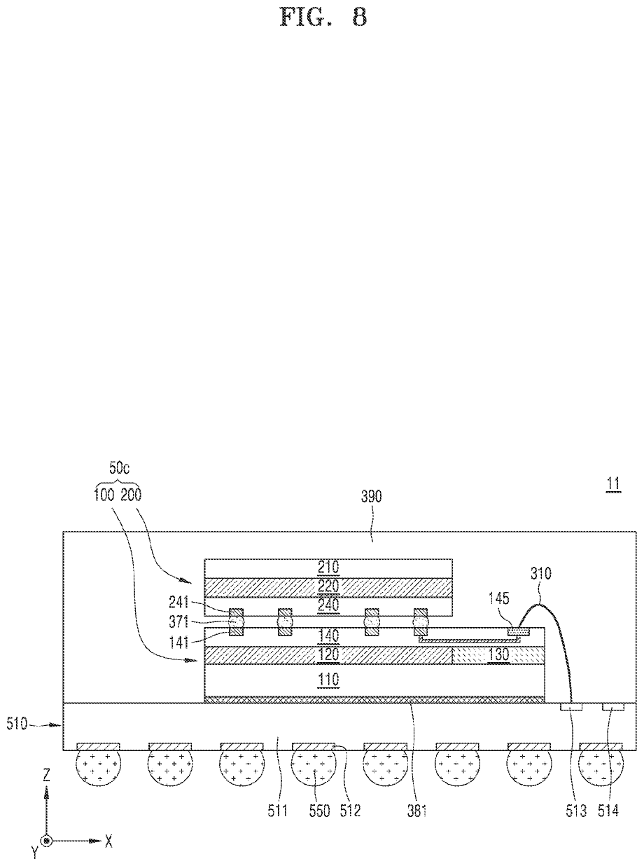

FIGS. 8 to 12 are cross-sectional views of semiconductor packages 11, 12, 13, 14, and 15 according to embodiments of the present inventive concept. Hereinafter, the semiconductor packages 11, 12,13, 14, and 15 shown in FIGS. 8 to 12 are described focusing on the differences from the semiconductor package 10 described with reference to FIG. 1.

Referring to FIG. 8, in the semiconductor package 11, a memory device 50c may include connection bumps 371 arranged between the first semiconductor chip 100 and the second semiconductor chip 200. The connection bumps 371 may electrically and physically connect the first semiconductor chip 100 to the second semiconductor chip 200. Each of the connection bumps 371 may be positioned between the corresponding first bonding pad 141 and the corresponding second bonding pad 241 so as to electrically and physically connect the corresponding first bonding pad 141 to the corresponding second bonding pad 241.

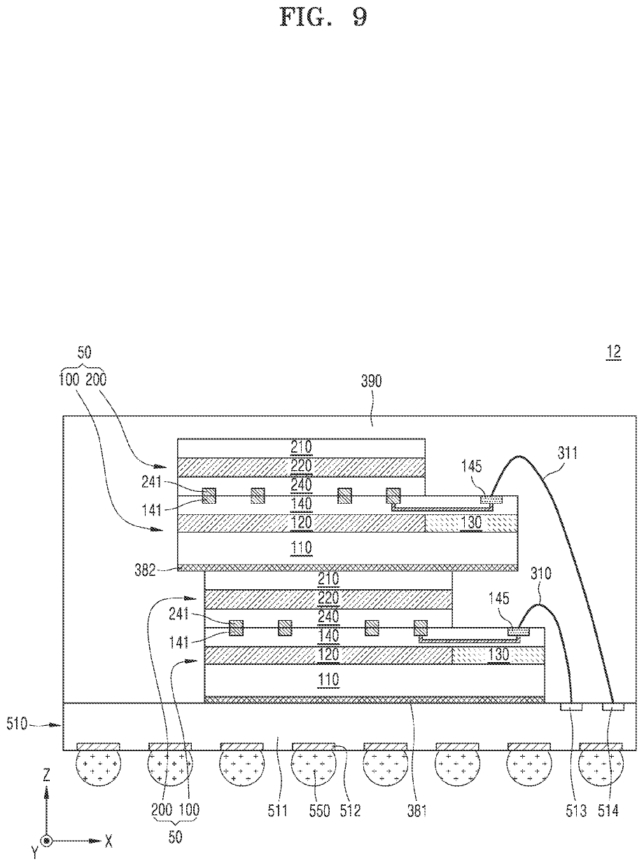

Referring to FIG. 9, the semiconductor package 12 may include memory devices 50 mutually stacked in a vertical direction. In FIG. 9, for example, the semiconductor package 12 includes two memory devices 50, i.e., the first memory device 50 and the second memory device 50, wherein the first memory device 50 refers to a lowermost memory device closest to the package substrate 510 and the second memory device 50 refers to a memory device above the first memory device 50. For example, the second memory device 50 is stacked on top of the first memory device 50.

An adhesive member 382 may be provided between the first memory device 50 and the second memory device 50 to fix the second memory device 50 onto the first memory device 50. In the second memory device 50, the input/output pad 145 of the second memory device 50 may be electrically connected to a second upper connection pad 514 through a second chip connection member 311 extending therebetween. The second chip connection member 311 may include a conductive wire. The second memory device 50 may be stacked offset from the first memory device 50 by a predetermined distance in a horizontal direction or X direction. The first upper connection pad 513 may be located to the left of the second upper connection pad 514. The second upper connection pad 514 may be located a first distance away from the first memory device 50 that is larger than a second distance in which the first upper connection pad 513 is located away from the first memory device 50.

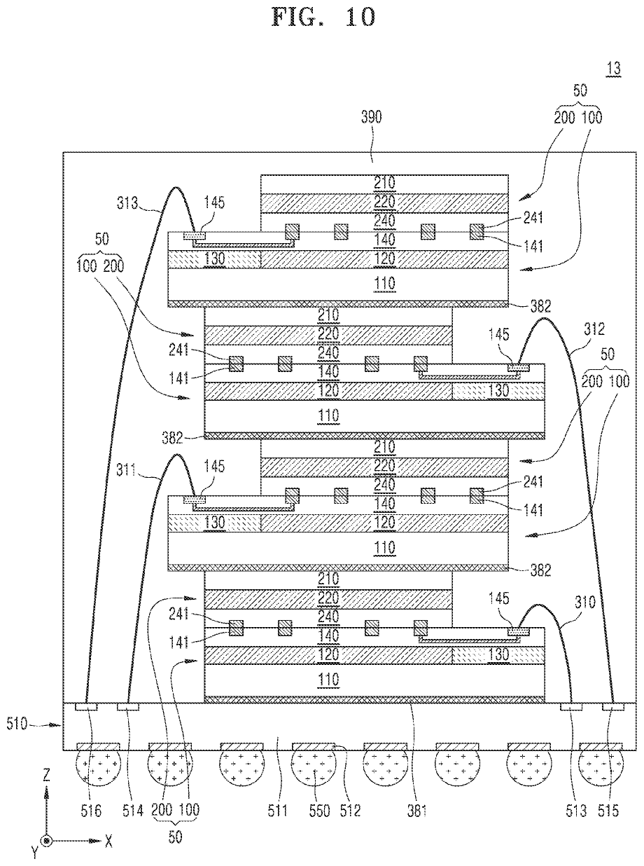

Referring to FIG. 10, the semiconductor package 13 may include memory devices 50 mutually stacked in a vertical direction. In FIG. 10, for example, the semiconductor package 13 includes four memory devices 50, i.e., a first memory device 50, a second memory device 50, a third memory device 50, and a fourth memory device 50, wherein the first memory device 50 may refer to a lowermost memory device closest to the package substrate 510, the second memory device 50 may refer to a memory device above the first memory device 50, the third memory device 50 may refer to a memory device above the second memory device 50, and the fourth memory device 50 may refer to a memory device above the third memory device 50. For example, the first memory device 50 may be formed on the package substrate 510, the second memory device 50 may be stacked on top of the first memory device 50, the third memory device 50 may be stacked on top of the second memory device 50, and the fourth memory device 50 may be stacked on top of the third memory device 50.

Each adhesive member 382 may be provided between the first memory device 50 and the second memory device 50, between the second memory device 50 and the third memory device 50, and between the third memory device 50 and the fourth memory device 50.

The second memory device 50 may be rotationally symmetric to the first memory device 50. For example, when the second memory device 50 rotates 180° with respect to a first rotational axis parallel to the vertical direction (e.g., Z direction) and then rotates 180° with respect to a second rotational axis parallel to the horizontal direction (e.g., X direction), the first memory device 50 and the second memory device 50 may have mirror-symmetric structures with respect to a reference plane (e.g., XY plane). In the second memory device 50, the input/output pad 145 of the second memory device 50 may be electrically connected to the second upper connection pad 514 through the second chip connection member 311 extending therebetween.

The third memory device 50 may be rotationally symmetrical to the second memory device 50. For example, when the third memory device 50 rotates 180° with respect to the first rotational axis parallel to the vertical direction (e.g., Z direction) and then rotates 180° with respect to the second rotational axis parallel to the horizontal direction (e.g., X direction), the second memory device 50 and the third memory device 50 may have mirror-symmetric structures with respect to a reference plane (e.g., XY plane). In the third memory device 50, the input/output pad 145 of the third memory device 50 may be electrically connected to a third upper connection pad 515 through a third chip connection member 312 extending therebetween.

The fourth memory device 50 may be rotationally symmetrical to the third memory device 50. For example, when the fourth memory device 50 rotates 180° with respect to the first rotational axis parallel to the vertical direction (e.g., Z direction) and then rotates 180° with respect to the second rotational axis parallel to the horizontal direction (e.g., X direction), the third memory device 50 and the fourth memory device 50 may have mirror-symmetric structures with respect to a reference plane (e.g., XY plane). In the fourth memory device 50, the input/output pad 145 of the fourth memory device 50 may be electrically connected to a fourth upper connection pad 516 through a fourth chip connection member 313 extending therebetween.

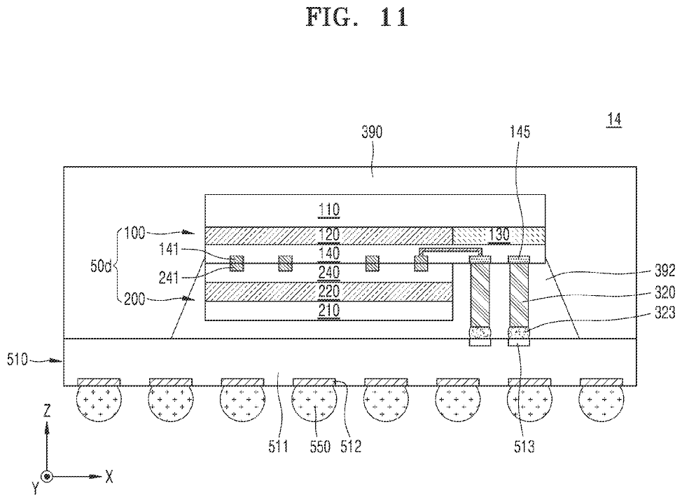

Referring to FIG. 11, in the memory device 50d of the semiconductor package 14, the second semiconductor chip 200 may be between the first semiconductor chip 100 and the package substrate 510. In the first semiconductor chip 100, the active surface of the first semiconductor substrate 110 may be a lower surface of the first semiconductor substrate 110, and the inactive surface of the first semiconductor substrate 110 may be an upper surface of the first semiconductor substrate 110. In the second semiconductor chip 200, the active surface of the second semiconductor substrate 210 may be an upper surface of the second semiconductor substrate 210, and the inactive surface of the second semiconductor substrate 210 may be an upper surface of the second semiconductor substrate 210. In the first semiconductor chip 100, the input/output pads 145 may be provided in a lower surface of the first semiconductor chip 100 facing the package substrate 510. In an embodiment, the input/output pads 145 are positioned in a region that does not overlap the second semiconductor chip 200 in the lower surface of the first semiconductor chip 100. First chip connecting members 320 may electrically connect the input/output pads 145 and the first upper connection pads 513 of the package substrate 510. Each of the first chip connection members 320 may include a columnar conductive pillar extending between the corresponding input/output pad 145 and the corresponding first upper connection pad 513. The conductive pillar may include metal or a conductive element, e.g., copper (Cu). In an embodiment, a conductive adhesive layer 323 is positioned between the first chip connecting members 320 and the first upper connection pads 513. The conductive adhesive layer 323 may include, for example, solder.

The semiconductor package 14 may include an underfill material layer 392 formed to fill a gap between the memory device 50d and the package substrate 510. The underfill material layer 392 may fill a gap between the second semiconductor chip 200 and the package substrate 510 and may fill a gap between the first semiconductor chip 100 and the package substrate 510. The underfill material layer 392 may surround sidewalls of each of the first chip connection members 320. The underfill material layer 392 may include, for example, epoxy resin. The underfill material layer 392 may be formed through, for example, a capillary underfill process. The underfill material layer 392 may support the first semiconductor chip 100 and the second semiconductor chip 200.

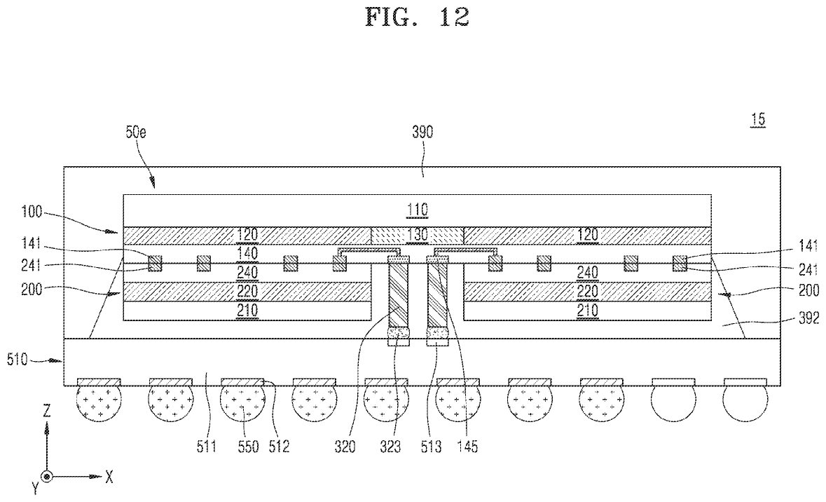

Referring to FIG. 12, in the semiconductor package 15, the memory device 50e may include a first semiconductor chip 100 and second semiconductor chips 200 connected to the first semiconductor chip 100. The second semiconductor chips 200 may be attached to a lower surface of the first semiconductor chip 100 and may be spaced apart from each other in a first lateral direction (e.g., X direction). For example, the second semiconductor chips 200 may be spaced apart from each other in a first lateral direction (e.g., X direction) with first chip connecting members 320 therebetween. In the first semiconductor chip 100, two first cell structures 120 may be spaced apart from each other with the first peripheral circuit structure 130 therebetween. One of the second semiconductor chips 200 is positioned to vertically overlap one of the first cell structures 120, and the other second semiconductor chip 200 is positioned to vertically overlap the other first cell structure 120. In the semiconductor package 15, the first peripheral circuit structure 130 may not vertically overlap the entirety of second semiconductor chips 200. In an embodiment, a pair of the second semiconductor chips 200 are spaced apart from one another in the X direction and the first peripheral circuit structure 130 only overlaps the space between the pair of the second semiconductor chips 200 in the X direction.

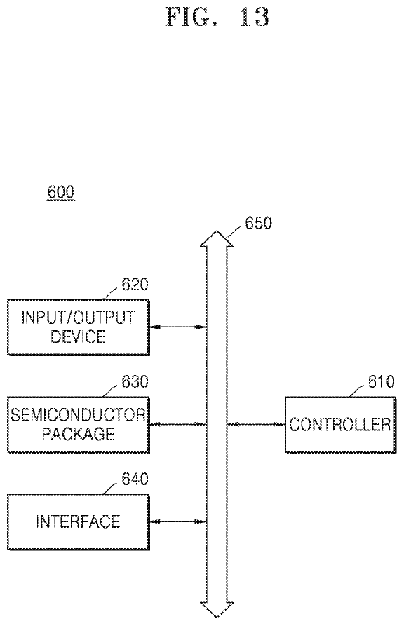

FIG. 13 is a block diagram for an example of a memory system 600 including a semiconductor package according to an embodiment of the present inventive concept.

Referring to FIG. 13, the memory system 600 may be applied to a personal digital assistant (PDA), a portable computer, a web tablet, a wireless phone, a mobile phone, a digital music player, a memory card, or any device capable of transmitting and/or receiving information in a wireless environment.

The memory system 600 includes a controller 610; an input/output device 620 such as a keypad, a keyboard, and a display; a semiconductor package 630; an interface 640 (e.g., an interface circuit); and a bus 650. The semiconductor package 630 communicates with the interface 640 through the bus 650.

The controller 610 includes at least one of a microprocessor, a digital signal processor, a microcontroller, and other similar processing devices. The semiconductor package 630 may be used to store commands executed by the controller 610. The input/output device 620 may receive data or signals from the outside of the memory system 600 or output data or signals to the outside of the memory system 600.

The semiconductor package 630 may include the memory devices 50, 50a, 50b, 50c, 50d, and 50e described with reference to FIGS. 1 to 12 and the semiconductor packages 10, 11, 12, 13, 14, and 15 described with reference to FIGS. 1 to 12. The semiconductor package 630 may be a memory chip package. The memory chip package may include a volatile memory chip and/or a non-volatile memory chip. The interface 640 transmits data to a communication network or receives data from the communication network.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate including a first pad;
a first memory device arranged on the package substrate and including first and second semiconductor chips stacked in a vertical direction; and
a first chip connection member electrically connecting the first semiconductor chip to the package substrate,
wherein the first semiconductor chip comprises:
a first cell structure having a memory cell for storing data;
a first peripheral circuit structure that communicates a signal provided from a source located outside the package substrate;
a first bonding pad; and
a first input/output pad vertically overlapping the first peripheral circuit structure and electrically connected to the first pad of the package substrate through the first chip connection member,
wherein the second semiconductor chip comprises:
a second cell structure having memory cells for storing data; and
a second bonding pad connected to the first bonding pad,
wherein a part of the first peripheral circuit structure protrudes from a first sidewall of the second semiconductor chip in a first direction so as not to overlap the second semiconductor chip.

2. The semiconductor package of claim 1,
wherein a peripheral circuit of the first peripheral circuit structure is electrically connected to a circuit of the first cell structure and a circuit of the second cell structure.

3. The semiconductor package of claim 1,
wherein the first semiconductor chip is disposed between the package substrate and the second semiconductor chip, and
wherein the first chip connection member includes a conductive wire extending between the first input/output pad and the first pad of the package substrate.

4. The semiconductor package of claim 1,
wherein the first bonding pad is directly coupled to the second bonding pad.

5. The semiconductor package of claim 1,
further comprising a connection bump disposed between the first bonding pad and the second bonding pad.

6. The semiconductor package of claim 1,
wherein a part of the first peripheral circuit structure protrudes from a second sidewall of the second semiconductor chip in a second direction so as not to vertically overlap the second semiconductor chip, where the second direction is different from the first direction.

7. The semiconductor package of claim 1,
further comprising a second memory device arranged on the first memory device and including third and fourth semiconductor chips stacked vertically; and
a second chip connection member electrically connecting the third semiconductor chip to a second pad of the package substrate,
wherein the third semiconductor chip comprises:
a third cell structure having a memory cell for storing data;
a second peripheral circuit structure that communicates a signal provided from a source located outside the semiconductor package;
a third bonding pad; and
a second input/output pad vertically overlapping the second peripheral circuit structure and electrically connected to the second pad of the package substrate through the second chip connection member,
wherein the fourth semiconductor chip comprises:
a fourth cell structure having a memory cell for storing data; and
a fourth bonding pad connected to the third bonding pad, and
wherein a length of the third semiconductor chip in the first direction is greater than a length of the fourth semiconductor chip in the first direction.

8. The semiconductor package of claim 1,
wherein the second semiconductor chip is disposed between the package substrate and the first semiconductor chip, and
the first chip connection member includes a conductive pillar extending between the first input/output pad and the first pad of the package substrate.

9. The semiconductor package of claim 8,
further comprising an underfill material layer arranged between the first semiconductor chip and the package substrate and between the second semiconductor chip and the package substrate.

10. The semiconductor package of claim 8,
further comprising another semiconductor chip connected to the first semiconductor chip and spaced apart from the second semiconductor chip in the first direction with the conductive pillar therebetween,
wherein the peripheral circuit of the first peripheral circuit structure is electrically connected to a circuit of a cell structure of the other semiconductor chip.

11. The semiconductor package of claim 1,
further comprising a molding layer covering the first semiconductor chip and the second semiconductor chip on the package substrate, wherein a part of the molding layer extends along the first sidewall of the second semiconductor chip.

12. The semiconductor package of claim 1,
wherein a thickness of the second semiconductor chip is between about 10 micrometers and about 100 micrometers.

13. A semiconductor package comprising:
a package substrate including a first pad;
a memory device disposed on the package substrate, the memory device including a first semiconductor chip disposed on the package substrate and a second semiconductor chip disposed on the first semiconductor chip; and
a conductive wire electrically connecting the first semiconductor chip to the package substrate,
wherein the first semiconductor chip comprises:
a first cell structure having a memory cell for storing data;
a first peripheral circuit structure that communicates a signal provided from a source located outside the semiconductor package;
a first interconnect structure including a first input/output pad electrically connected to the first pad of the package substrate through the conductive wire and a first bonding pad, wherein the first input/output pad is vertically overlapped with the first peripheral circuit structure,
wherein the second semiconductor chip comprises:
a second cell structure having a memory cell for storing data; and
a second interconnect structure including a second bonding pad directly coupled to the first bonding pad,
wherein a part of the first peripheral circuit structure protrudes from a sidewall of the second semiconductor chip in a first direction so as not to vertically overlap the second semiconductor chip, and
wherein a thickness of the second semiconductor chip is smaller than a thickness of the first semiconductor chip.

14. The semiconductor package of claim 13,
wherein a second sidewall of the second semiconductor chip is vertically aligned with one sidewall of the first semiconductor chip.

15. The semiconductor package of claim 13,
wherein the first semiconductor chip protrudes from a second sidewall of the second semiconductor chip in a second direction that is different from the first lateral direction.

16. A memory device comprising:
a first semiconductor chip including a first cell structure having a memory cell for storing data, a first peripheral circuit structure for communicating a signal provided from a source located outside the memory device, a first bonding pad, and a first input/output pad, wherein the first input/output pad vertically overlaps the first peripheral circuit structure; and
a second semiconductor chip stacked on the first semiconductor chip, including a second cell structure having a memory cell for storing data and a second bonding pad connected to the first bonding pad,
wherein a length of the first semiconductor chip in a first direction is greater than a length of the second semiconductor chip in the first direction,
wherein a part of the first peripheral circuit structure protrudes from a first sidewall of the second semiconductor chip in the first direction so as not to vertically overlap the second semiconductor chip.

17. The memory device of claim 16,
wherein a peripheral circuit of the first peripheral circuit structure is electrically connected to a circuit of the first cell structure and a circuit of the second cell structure.

18. The memory device of claim 16,
wherein the first bonding pad is directly coupled to the second bonding pad.

19. The memory device of claim 16,
further comprising a connection bump arranged between the first bonding pad and the second bonding pad.

20. The memory device of claim 16,
wherein a thickness of the second semiconductor chip is smaller than a thickness of the first semiconductor chip, and
the thickness of the second semiconductor chip is between about 10 micrometers and about 100 micrometers.
